(19) United States
(12) Patent Application Publication
(10) Pub. No.: US 2003/0201924 A1
(43) Pub. Date: Oct. 30, 2003

(54) Digital-to-analog converter

(76) Inventors: Kadaba R. Lakshmikumar, Basking Ridge, NJ (US); Gong Gu, Bridgewater, NJ (US)

Correspondence Address: Douglas A. Chaikin, PENINSULA IP GROUP, Suite 101, 2290 North First Street, San Jose, CA, 95131, US

(21) Appl. No.: 10/134,355

(22) Filed: Apr. 27, 2002

(51) Int. Cl. H03M 1/80

(52) U.S. Cl. 341/153

(57) ABSTRACT

A digital-to-analog converter for converting binary digital input signals into an analog output signals. The converter has a thermometer decoder for decoding a most significant number of the binary bits of the digital input signal into a number of decoder outputs. Apparatus connected to the thermometer decoder and enabled by the decoder outputs in combination with a least significant number of binary bits of the digital input signal generate an analog output signal corresponding to the binary bit digital input signal.

### FIELD OF THE INVENTION

The present invention relates to digital-to-analog converters and in particular to digital-to-analog converters having monotonic transfer characteristics with reduced decoder complexity and relaxed unit cell matching requirements with compact size.

### BACKGROUND OF THE INVENTION

High speed digital systems are widely installed in many areas of the world and the United States. Typically, these systems operate in a binary mode wherein voltage pulses representing O's and 1's are used to generate information in operation of the system binary circuits. Although these types of systems are primarily binary in design, the internal circuitry may require analog signals to enable the systems to operate in the binary mode. A processor may be programmed to generate digital signals that are applied to a digital-to-analog converter which responds to the received digital signals by generating analog signals that vary in value in accordance with the received digital signals. Although this is one example, digital-to-analog converters are used in a broad spectrum of applications such as instrumentation, signal processing, control systems and the like.

One type of digital-to-analog converter used in the prior art has a thermometer decoder that decodes an m binary bit digital input signal into an analog output signal that corresponds in value to the binary input signal. The thermometer decoder typically has 2^{m}−1 outputs wherein each output controls apparatus to connect one of 2^{m}−1 matched unit current sources to an output bus to generate a value of current corresponding to the digital input signal. For example, a seven bit binary input signal of 0000001 applied to the input of the thermometer decoder would enable one of the decoder outputs to connect one current source to the digital-to-analog converter output bus and a seven bit binary input signal of 0000110 would enable the thermometer decoder to connect six of the unit current sources to the output bus. Thus, when the digital input signal is increased or decreased by a number of n bits, n unit current sources will be added to or subtracted from those unit current sources that were previously connected to the converter output bus. The architecture of this type of digital-to-analog converter requires 2^{m-1} current sources for the operation of the converter. A problem exists with this design in that although it is inherently monotonic it requires that the number of current sources increase exponentially with the size of the m binary bit input signal.

A segmented digital-to-analog converter has been designed to overcome the above exponential growth complexity. This type of converter requires that the m bit digital input signal be divided into groups of least significant i and most significant bits k of the digital input signal. The converter has a thermometer decoder for receiving and decoding the most significant bits k of the binary bit digital input signal. The thermometer decoder decodes the most significant bits k into 2^{k}−1 outputs and each thermometer decoder output is connected to a current source having a value of 2^{l} times the unit current where l is the number of least significant bits and k+l is equal to m, the width of the digital input signal. Each of the l least significant bits of the input signal is connected to a current source having the decimal value of the particular bit times the unit current. When an eight bit binary digital input signal D(7,0) having a binary value 00010011, equal to a decimal number 19, is applied to this type of digital-to-analog converter, the thermometer decoder decodes the four most significant k bits 0001 into an output that connects a 16× unit current source to the output bus. The least significant l bits D(3,0) 0011 operate the converter to connect 2× and 1× unit current sources to the output bus in combination with the 16× current source. This design is very compact when compared to the basic thermometer decoder design. However a problem arises in that this design is not inherently monotonic when transitioning from a digital input signal where all the least significant bits are one to the next digital input signal. In order to achieve monotonicity, an 8 bit device matching accuracy is required in this example.

Accordingly, a need exists for a monotonic digital-to-analog converter having a compact design using relatively few components yet requiring lower matching accuracy among unit current sources.

### SUMMARY OF THE INVENTION

It is an object of the invention to provide a digital-to-analog converter for converting a binary bit digital input signal into an analog output signal having a thermometer decoder for decoding a most significant number k of the binary bits of the digital input signal into 2^{k}−1 decoder outputs.

It is also an object of the invention to provide a digital-to-analog converter having a thermometer decoder for decoding a most significant number k of m binary bits of a digital input signal into 2^{k}−1 decoder outputs and having 2^{k} groups of logic apparatus wherein each group is connected to a thermometer decoder output and arranged to receive a least significant number l of the binary bits of the digital input signal wherein k+l=m and which are enabled by the decoder outputs in combination with ones of the l binary bits to generate analog output signals in accordance with values of the digital input signals.

It is also an object of the invention to provide a digital-to-analog converter having a thermometer decoder for decoding a most significant number k of m binary bits of a digital input signal into 2^{k}−1 decoder outputs and having 2^{k} groups of logic apparatus wherein each group is connected to a thermometer decoder output and arranged to receive a least significant number l of the binary bits of the digital input signal wherein k+l=m and which have l+1 binary weighted current sources connected to logic apparatus operated by the logic devices in response to the converter receipt of the k and l bits of the digital input signal for generating analog signals corresponding in value to the received digital input signal.

In a preferred embodiment of the invention, a digital-to-analog converter for converting an m binary bit digital input signal into an analog output signal has a decoder for decoding a most significant number k of the binary bits of the digital input signal into 2^{k}−1 decoder outputs. Apparatus connected to the decoder and enabled by the decoder outputs in combination with a least significant number l of binary bits of the digital input signal where k+l=m generates the analog output signal in accordance with a value of the digital input signal.

Also in accordance with an embodiment of the invention, a digital-to-analog converter for converting an m binary bit digital input signal having a number of least significant bits l and a number of most significant bits k where k+l=m into an analog output signal has a thermometer decoder for decoding the k binary bits of the digital input signal into 2^{k}−1 decoder outputs. The converter has k groups of logic apparatus with each group connected to one of the thermometer decoder outputs and wherein each group has l+1 logic gates with one input of each logic gate connected to one thermometer decoder output or a logical zero signal and another input connected to an output of one of another l+1 logic gates. Each group has 2^{l} unit current sources connected to the output of the group logic gates and is enabled by the logic gates to generate an output of analog current in accordance with the digital input signal applied to the converter.

### BRIEF DESCRIPTION OF THE DRAWINGS

For a further understanding of the objects and advantages of the present invention, reference should be made to the following detailed description, taken in conjunction with the accompanying drawing figures, in which like parts are given like reference numerals and wherein:

FIG. 1 is a block diagram of a fully thermometer decoded digital-to-analog converter for converting binary bit digital input signals into analog signals,

FIG. 2 is a block diagram of a digital-to-analog converter using a thermometer decoder for interconnecting current sources in accordance with principles of the invention to convert the binary bit digital input signals into the analog signals, and

FIG. 3 is a block diagram of a digital-to-analog converter using a thermometer decoder for interconnecting solid state devices to an output bus to provide sources of current in accordance with principles of the invention to convert binary bit digital input signals into analog signals.

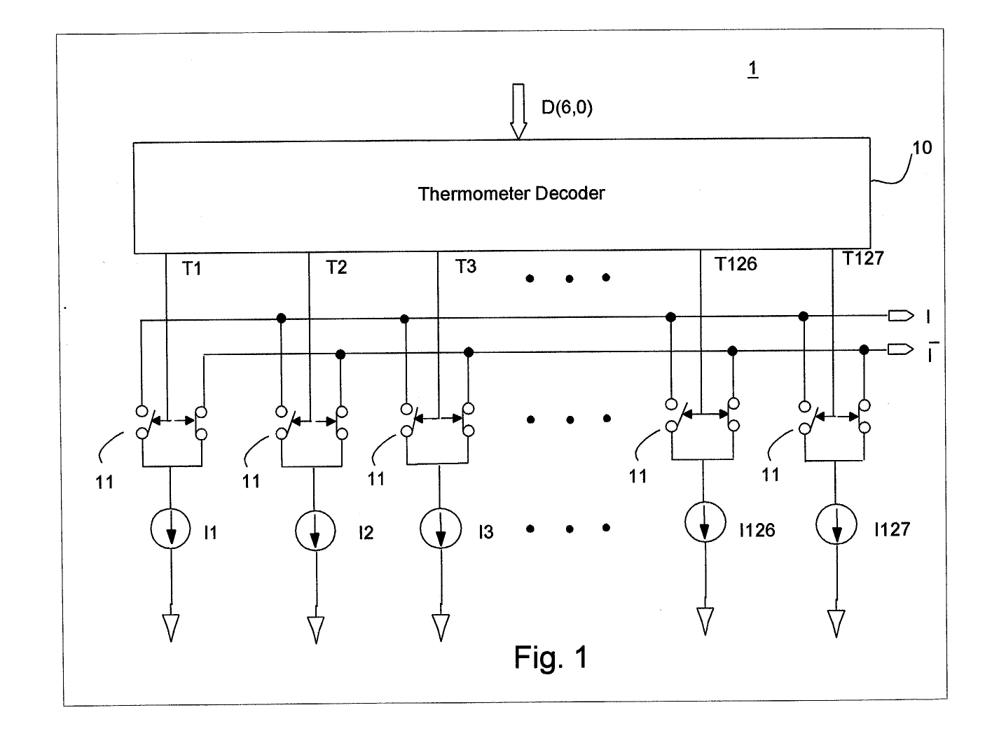

The logic component circuitry of the apparatus set forth in FIGS. 1 through FIG. 3 has solid state and electrical elements, the individual operation of which are well known in the art and the details of which need not be disclosed for an understanding of the invention. Typical examples of the logic circuitry are described in numerous textbooks. For example, such types of logic circuitry, among others, are described by J. Millman and H, Taub in Pulse, Digital and Switching Waveforms, 1965, McGraw-Hall, Inc., H. Alex Romanowitz and Russell E. Puckett in Introduction to Electronics, 1968, John Wiley & Sons, Inc., E. J. Angelo, Jr. in Electronic Circuits, Second Edition, 1958, McGraw Hill, Inc. Circuit designs of integrated circuits are described by D. A. Johns and K. Martin in Analog Integrated Circuit Design, John Wiley & Sons, 1997, pp 477 and by K. R. Lakshmikumar et el. in A Baseband Codec for Digital Cellular Telephony, IEEE J. Solid-State Circuits, vol. SC-26, pp 1951, December 1991.

### DETAILED DESCRIPTION OF THE INVENTION

With particular reference to FIG. 1 of the drawing, a digital-to-analog converter 1 consists of a thermometer decoder 10 arranged to receive m binary bits of a digital input signal and to decode the received m number of binary bits into 2^{m}−1 outputs. Thus, in a typical example, an input seven bit digital binary word D(6,0) would be decoded by thermometer decoder 10 into 127 outputs T1 through T127. Each of the outputs T1 through T127 enable apparatus 11 to disconnect one of a number of the unit current sources l1 through l127 from an T output bus and connect the unit current source to an l output bus. When the digital input signal D(6,0) is increased or decreased by n bits, n number of unit current sources l1 through T127 are added to or subtracted from those previously connected to the l output bus. A binary equivalent of decimal one digital input signal D(6,0) would result in apparatus 11 connected to thermometer decoder input T1 to disconnect unit current source l1 from the T output bus and connected it to the l output bus. When the binary digital input signal is increased to a binary equivalent of decimal two, the apparatus 11 connected to thermometer decoder 10 output T2 operates to disconnect unit current source l2 from the T output bus and connect it in parallel with the l1 unit current source to the l output bus such that the current generated by unit current source l2 is added to the current generated by unit current source l1. The architecture of digital-to-analog converter 10 is inherently monotonic regardless of matching among the l27 unit current sources l1 through l127.

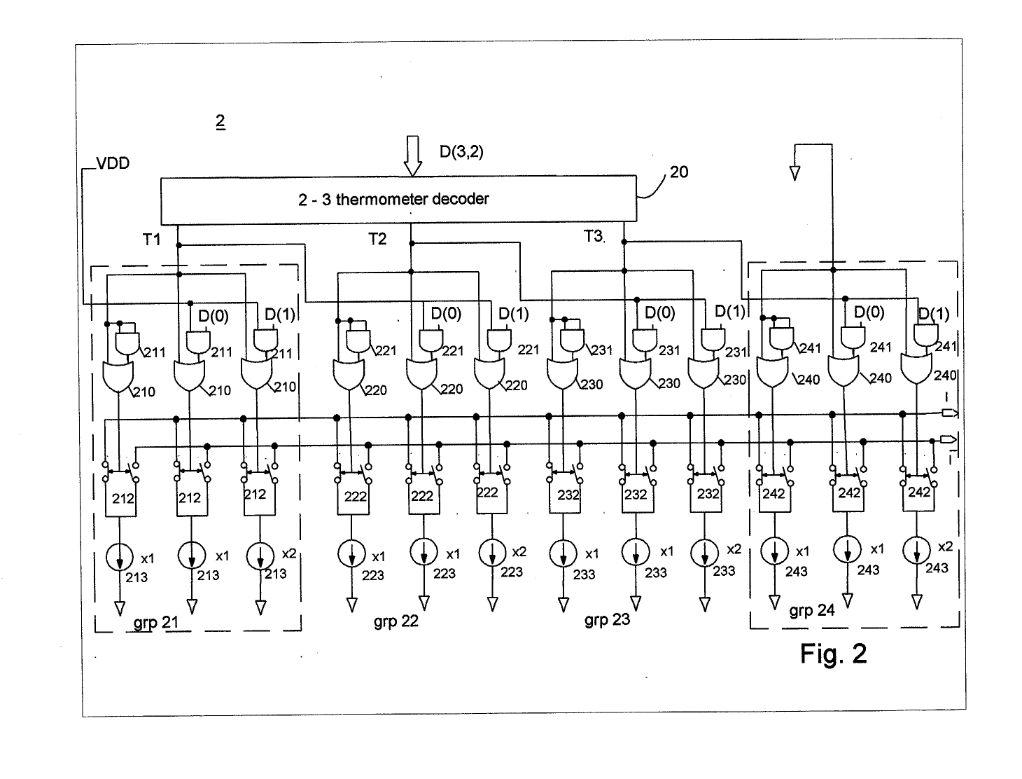

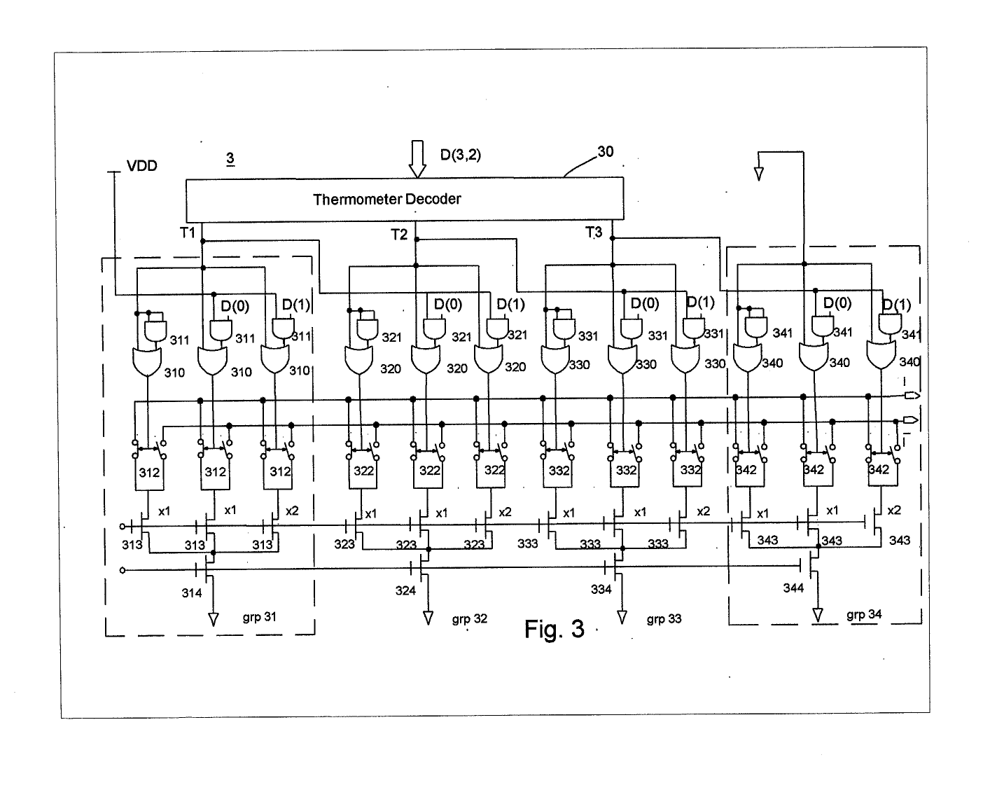

In an exemplary embodiment of the invention, the digital-to-analog converters 2 and 3, set forth in FIGS. 2 and 3 of the drawing, are arranged to convert m binary bit digital input signals into analog signals having values corresponding to values of the binary bit digital input signals. It is assumed for the present embodiment that the digital input signal is four bits in width such that m is equal to four. It is further assumed that the four binary bit digital input signal has a number of l least significant bits (LSB) where l is equal to two and a k number of most significant bits (MSB) where k is equal to two such that l+k is equal to m, the value of the m number of bits of the digital input signal. It is to be understood that m, l and k could have other values in accordance with the principles of the invention. For example, digital-to-analog converters 2 and 3 could also convert an eight binary bit digital input signal having four LSB's and four MSB's with m =8, l=4, and k=4 and k+l=8, the value of m. Similarly, other values of m binary bit digital input signals could be converted by digital-to-analog converters 2 and 3 into analog output signals.

Both converters 2 and 3, FIGS. 2, 3, have thermometer decoders 20 and 30, respectively, for decoding a most significant number k of the binary bits of the digital input signal into 2^{k}−1 decoder outputs. For a four binary bit digital input signal D(3,0), having l=2 LSB's and k=2 MSB's, thermometer decoders 20 and 30 decode the k=2 MSBs' D(3,2) into 2^{k}−1 decoder outputs T1, T2 and T3. Apparatus connected to the thermometer decoders 20 and 30 is enabled by the decoder outputs T1, T2 and T3 in combination with the l LSB's D(1,0) of the digital input signal for generating analog output signals in accordance with a value of the digital input signals. Each digital-to-analog converter 2 and 3 has logic apparatus connected to ones of the thermometer decoder outputs T1, T2 and T3 and is arranged to receive the l=2 binary bits D(1,0) of the digital input signal. Current sources are operated by the logic apparatus in response to the converters receipt of the most and least significant number k and l bits of the digital input signal for generating analog signals corresponding in value to the received digital input signal.

The logic apparatus of each digital-to-analog converter 2 and 3 has 2^{k}=4 groups of logic components wherein inputs of each group 21 through 23 are connected to one of the thermometer decoder outputs T1, T2 and T3 and are arranged to receive the l least significant bits of the digital input signal with outputs connected with ones of the current sources. Logic components of each group consists of l+1 OR logic gates, such as OR logic gates 210, 330 each having one input connected to one of the thermometer decoder outputs T1, T2 and T3, or in the case of groups 24 and 34, one input connected to a logical zero source, and an output connectable to ones of the group current sources 213, 223, 233 and 243 for converter 2. In addition, each group has a plurality of AND gates such as AND gates 211, 221, 231, 241 and 311, 321, 331, 341 each having one input for receiving one of the l LSB's of the input digital signal and each having an output connected to another input of ones of the OR logic gates 210, 220, 230, 240. Groups 2^{k}−1, such as groups 22, 23, 24 and 32, 33, 34, each have an l number of AND gates each having another input, in addition to one input for receiving one of the l LSB's of the digital input signal, connected to one of the thermometer decoder outputs T1, T2 and T3 preceding the thermometer decoder output connected to the input of the group OR gate connected to the AND gate output. Thus, group 22 has 2 AND gates 221 each having another input, in addition to one input for receiving one of the 2 LSB's D(1,0) of the digital input signal, connected to the thermometer decoder output T1 preceding the thermometer decoder output T2 connected to the input of the group 22 OR gates 220 connected to the AND gate outputs. A first group 21 has an l number of two AND gates 211 each having another input, in addition to one input for receiving one of the LSB bits D(1,0), connected to a logical one voltage source VDD.

Each of the 2^{k} logic groups 21 through 24 of digital-to-analog converter 2 has a group of 2^{l} unit current sources 213, 223, 233, 243 wherein the current sources are connected to the output of the group OR gates 210, 220, 230, 240, respectively, and which are enabled to generate an output of analog current in accordance with the digital input signal applied to the converter 2. In the present embodiment of the invention, logic group 21 has four unit current sources 213 wherein one unit current source x1 is connected to the output of the combination of a first OR gate 210 and AND gate 211 having inputs connected the thermometer decoder output T1. Another one unit current source x1 is connected to the output of the OR gate 210 combined with AND gate 211 having inputs connected to the logical one voltage source VDD and to the first LSB D(0) of the digital input signal. A two unit current source x2, or two one unit current sources x1, are connected to the output of the OR gate 210 combined with AND gate 211 having inputs connected to the logical one voltage source VDD and to the second LSB D(1) of the digital input signal.

In the remaining logic component groups 22 through 24 of the present example, one unit current source x1 is connected to the output of the combination of a first OR gate and AND gate having inputs connected to the thermometer decoder outputs T2, T3, and a logical zero value respectively. Another one unit current source x1 is connected to the output with OR gates each combined with AND gates having inputs connected to a preceding thermometer decoder 20 output T1, T2 and T3, respectively, and to the first LSB D(0) of the digital input signal. A two unit current source x2, or two one unit current sources x1, are connected to the output of the OR gate combined with an AND gate having inputs connected to the preceding thermometer decoder 20 output T1, T2 and T3, respectively, and to the second LSB D(1) of the digital input signal.

In another embodiment of the invention, an alternative architecture of the digital-to-analog converter may have m logic groups 31 through 34, FIG. 3, having current sources comprising 2¹ current source cascode transistors 313, 323, 333, 343. Similar to the unit current sources set forth in FIG. 2, the cascode transistors 313, 323, 333, 343, FIG. 3, are connected in the same manner as the unit current sources of FIG. 2 to the OR gates of the logic groups. Thus in logic group 31, a first x1 cascode transistor 313 can be connected to the OR gate output of the combined OR and AND gates 310 and 311 having all inputs connected to the T1 output of thermometer decoder 30. Second x1 and x2 cascode transistors 313 can be connected to the OR gate output of the OR and AND gate combinations having inputs connected to the logic one source VDD and the LSBs' D(0) and D(1) of the digital input signal. In a similar manner as set forth for converter 2, FIG. 2, the cascode transistors for the remaining logic groups 32, 33 and 34 are connected to the outputs of the OR and AND gates in the same manner as the unit current sources 212 of FIG. 2. Thermometer decoder 20 and 30 decoding of the MSBs' results in inherent monotonicity at the major carry transitions and the matching of the cascode transistors maintain the monotonicity throughout the entire digital-to-analog transfer characteristic. To achieve this characteristic only an l=2 bit matching accuracy within each group is required. A voltage V_{casc} applied to the cascode transistors 313, 323, 333 and 343 and the operation of bias transistor 314, 324, 334 and 344 connected to the group cascode transistors to the application of a V_{bias} voltage maintains proper operation of the cascode transistors.

The digital-to-analog converters 2 and 3, FIGS. 2 and 3, both have a pair of output buses l and T and switching apparatus such as 212 and 312 connected to outputs of the group OR gates 210, 220, 230, 240 and 310, 320, 330, 340 and the 2^{l} current sources 213, 223, 233, 243 and cascode transistors 313, 323, 333, 343. The switching apparatus is operated by the group OR gates for selectively connecting the current sources 213, 223, 233, 243 and cascode transistors 313, 323, 333, 343 to the output buses l and T to generate analog output currents in accordance with the binary digital input signal. Although details of the switching apparatus is omitted for simplicity, various types of switching apparatus may be used. For example, in high speed applications, control signals of the switching apparatus may be aligned to a clock signal by logic devices to minimize errors.

In operation of the exemplary embodiment of the invention, a four bit wide digital input signal D(3,0) of 0011 having a decimal value of 3 is applied to digital-to-analog converters 2 and 3 set forth in FIGS. 2 and 3. For this digital input signal where the MSB D(3,2) inputs are binary zeros, the T1, T2 and T3 outputs of thermometer decoders 20 and 30 are a logical zero. With the LSB D(1,0) bits of the digital input signal each being a logical one, the AND gates 211 and 311 of logic groups 21 and 31, respectively, enable OR gates 210, 310 having an input connected to the output of the AND gates 211, 311 to operate the switching apparatus 212, 312. The operation of the switching apparatus 212 of digital-to-analog converter 2, FIG. 2, connects unit current sources 213 x1 and x2 of logic group 21 to output bus l so that three unit current sources 213 in accordance with the decimal value of 3 of the digital input signal is connected to the converter output bus 1. In a similar manner, digital-to-analog converter 30, FIG. 3, cascode transistors 313 x1 and x2 are connected to output bus l so that three current sources are generated in response to the digital input signal 0011. When a four bit wide digital input signal D(3, 0) of 0101 having a decimal value of 5 is applied to digital-to-analog converters 2 and 3, FIGS. 2 and 3, the MSB D(2) enables thermometer decoders 20 and 30 output T1 in combination with the D(0) inputs to group AND gates. In groups 21 and 31, all three OR gates 210, 310, respectively, are enabled to connect unit current sources 213 and cascode transistors 312 x1, x1 and x2 to output bus 1. In addition the thermometer decoders 20 and 30 output T1, in combination with the input LSB D(0), enables an AND and OR gates 221, 220 and 321, 320, respectively, of groups 22 and 32 to connect a x1 unit current source 223 and cascode transistor 323 to the converter's l bus so that five unit current sources and cascode transistors provide the converters analog output signal. Similar operations of the logic groups occur for various digital input signals applied to digital-to-analog converters 20 and 30 to generate corresponding analog signal outputs.

It is obvious from the foregoing that the facility, economy and efficiency of digital-to-analog converters are improved by apparatus of a compact architecture with significantly relaxed device matching requirements designed to be monotonic when transitioning from digital input signal where all the least significant bits are a logical one to the next digital input signal. While the foregoing detailed description has described several embodiments of digital-to-analog converters for converting four bit wide digital input signals to corresponding analog output signals it is illustrative only and is not limiting of the disclosed invention. Particularly, digital-to-analog converters could be designed in accordance with the principles of the invention to convert various widths of digital input signals into corresponding analog signals. Thus, the invention is to be limited only by the claims set forth below.

What is claimed is:

1. A digital-to-analog converter for converting an m binary bit digital input signal into an analog output signal comprising
a decoder for decoding a most significant number k of binary bits of the digital input signal into 2^{k}−1 decoder outputs, and
means connected to the decoder and enabled by the decoder outputs in combination with a least significant number l of binary bits of the digital input signal where k+l=m for generating the analog output signal in accordance with a value of the digital input signal.

2. The digital-to-analog converter set forth in claim 1 wherein the decoder comprises
a thermometer decoder for receiving the k binary bits of the digital input signal and decoding the received k binary bits into the 2^{k}−1 decoder outputs.

3. The digital-to-analog converter set forth in claim 2 wherein the generating means comprises
logic means connected to ones of the thermometer decoder outputs and arranged to receive the l binary bits of the digital input signal.

4. The digital-to-analog converter set forth in claim 3 wherein the generating means comprises
current sources connected to the logic means and operated by the logic means in response to the converter receipt of the most and least significant number k and l bits of the digital input signal for generating analog signals corresponding in value to received digital input signals.

5. The digital-to-analog converter set forth in claim 4 wherein the logic means comprises
groups of logic components wherein inputs of each group of the logic components are connected to one of the thermometer decoder outputs and arranged to receive the least significant bits l of the digital input signal and having outputs connected with ones of the current sources.

6. The digital-to-analog converter set forth in claim 5 wherein each group of the logic components comprises
a plurality of OR logic gates each having one input connected to one of the thermometer decoder outputs and an output connectable to ones of the current sources, and
a plurality of AND logic gates each having one input for receiving one of the least significant bits l of the input digital signal and each having an output connected to another input of ones of the OR logic gates.

7. The digital-to-analog converter set forth in claim 6 wherein the logic component groups comprises
l+1 OR logic gates each having one input connected to the output of one of l AND logic gates and wherein the other input of each OR logic gate is connected to a thermometer decoder output.

8. The digital-to-analog converter set forth in claim 7 wherein the logic circuits of 2^{k}−1 of the logic component groups comprises
an l number of AND logic gates each having another input in addition to one input for receiving one of the least significant bits of the digital input signal connected to one of the thermometer decoder outputs preceding the thermometer decoder output connected to the input of the OR logic gates connected to the AND logic gates output.

9. The digital-to-analog converter set forth in claim 8 wherein a first one of the logic component groups comprises
an l number of AND logic gates each having another input in addition to one input for receiving one of the least significant bits of the digital input signal connected to a logical one source.

10. The digital-to-analog converter set forth in claim 9 wherein the current sources comprises
groups of l=1 binary weighted current sources wherein the unit current sources are connectable to the output of the group OR logic gates and enabled thereby to generate an output of analog current in accordance with the digital input signal applied to the digital-to-analog converter.

11. The digital-to-analog converter set forth in claim 10 wherein the current sources comprises
groups of 2^{l} unit cascode transistors wherein the transistors are connectable in parallel to the output of the group OR gates and enabled to generate an output of analog current in accordance with the digital input signal applied to the converter.

12. The digital-to-analog converter set forth in claim 10 comprising
a pair of output buses, and
switching means connected to outputs of the group OR logic gates and the 2^{l} current sources and operated by OR logic gates for selectively connecting the current sources to the output buses to generate analog output currents in accordance with the binary digital input signal.

13. A digital-to-analog converter for converting an m binary bit digital input signal into an analog output signal comprising
a thermometer decoder for decoding a most significant number k of the m binary bits of the digital input signal into 2^{k}−1 decoder outputs, and
2^{k} groups of logic means wherein each group is connected to a thermometer decoder output and arranged to receive a least significant number l of the binary bits of the digital input signal wherein k+l=m and which is enabled by the decoder outputs in combination with ones of the l binary bits to generate analog output signals in accordance with values of the digital input signals.

14. The digital-to-analog converter set forth in claim 13 wherein the each group of logic means comprises
2^{l} unit current sources,
l+1 OR logic gates each having one input connected to one of the thermometer decoder outputs and an output connectable to ones of the current sources, and
l AND gates each having one input for receiving one of the least significant bits l of the input digital signal and each having an output connected to another input of ones of the OR logic gates wherein enablement of ones of the thermometer decoder outputs and ones of the l bits of the digital input signal enable ones of the current sources to generate the analog output signals.

15. The digital-to-analog converter set forth in claim 14 wherein the converter comprises
a pair of output buses, and
switching means operated by ones of the logic means OR logic gates in response to the digital input signal for selectively connecting ones of the current sources to the buses.

16. The digital-to-analog converter set forth in claim 14 wherein a first one of the logic means group comprises
an l number of AND logic gates each having another input in addition to one input receiving one of the least significant bits of the digital input signal connected to a logical one voltage source.

17. The digital-to-analog converter set forth in claim 16 wherein 2^{k}−1 of the logic means comprises
an l number of AND logic gates each having another input in addition to one input receiving one of the least significant bits of the digital input signal connected to one of the thermometer decoder outputs preceding the thermometer decoder output connected to the input of the group OR logic gates connected to the AND logic gate output.

18. A digital-to-analog converter for converting an m binary bit digital input signal having a number of least significant bits l and a number of most significant bits k where k+l=m into an analog output signal comprising
a thermometer decoder for decoding the k binary bits of the digital input signal into 2^{k}−1 decoder outputs,
m groups of logic means with each group connected to one of the thermometer decoder outputs and wherein each group has l+1 OR logic gates with one input of each OR logic gate connected to the one thermometer decoder outputs and another input of the OR logic gate connected to an output of one of l AND logic gates, and
m groups of 2^{l} unit current sources wherein the current sources are connected to the output of the group OR logic gates and enabled to generate an output of analog current in accordance with the digital input signal applied to the converter.
